(19) United States
(12) Patent Application Publication
(10) Pub. No.: US 2026/0280562 A1
(43) Pub. Date: Sep. 17, 2026

(54) Weak Pull-Up Circuits And Methods Having Leakage Current Compensation

(71) Applicant: Altera Corporation, San Jose, CA (US)

(72) Inventors: Pai Ho Bong, Bayan Lepas (MY); Navindra Navaratnam, Portland, OR (US); Seh Leong Goh, George Town (MY)

(73) Assignee: Altera Corporation, San Jose, CA (US)

(21) Appl. No.: 19/076,330

(22) Filed: Mar. 11, 2025

(51) Int. Cl. H03K 19/003; G01R 31/52

(52) U.S. Cl. CPC H03K 19/00384; G01R 31/52

(57) ABSTRACT

An integrated circuit includes an output driver circuit coupled to a pad of the integrated circuit. The integrated circuit also includes a weak pull-up circuit coupled to the pad. The weak pull-up circuit includes a resistor and a leakage current sensing circuit coupled to the resistor. The leakage current sensing circuit generates a compensation current in the resistor that compensates for a leakage current through the output driver circuit when the output driver circuit is disabled.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the configurable integrated circuit to perform the functions of the custom circuit design.

### BRIEF DESCRIPTION OF DRAWINGS

FIG. 1 is a diagram that illustrates an example of a weak pull-up circuit that includes a leakage current sensing circuit that compensates for leakage current through an output driver circuit.

FIG. 2A illustrates an example of a level shifter circuit that generates the enable bar signal shown in FIG. 1 using an input voltage signal.

FIG. 2B illustrates an example of a voltage generator circuit that generates another signal shown in FIG. 1.

FIG. 3 is a diagram that illustrates an example of a configurable logic integrated circuit that can implement techniques disclosed herein.

FIG. 4A is a block diagram of a system that can be used to implement a circuit design to be programmed into a programmable logic device using design software.

FIG. 4B is a diagram that depicts an example of a programmable logic device that includes fabric dies and base dies that are connected to one another via microbumps.

FIG. 5 is a block diagram illustrating a computing system configured to implement one or more aspects of the techniques disclosed herein.

### DETAILED DESCRIPTION

Some types of configurable integrated circuits (ICs), such as field programmable gate arrays (FPGAs), have weak pull-up circuits that are coupled to pads. The pads are external terminals of the ICs. Each of the weak pull-up circuits is designed to pull the voltage at a pad to a logic high state when a driver circuit that is external to the integrated circuit (IC) is driving an input signal to the pad. A weak pull-up circuit can also pull the voltage at a pad to a logic high state when no other signal is present at the pad, and the pad is unused.

In advanced technology process nodes for semiconductor ICs, leakage current from pads can be significantly larger than in older process nodes. In a typical weak pull-up circuit coupled to a pad in an IC, a driver circuit coupled to the same pad can draw significant leakage current from the pad when the weak pull-up circuit is enabled and the driver circuit is disabled. The leakage current through the driver circuit causes the current through the weak pull-up circuit to decrease more as the temperature of the IC increases. In addition, the leakage current through the driver circuit causes the resistance of the weak pull-up circuit to increase more as the temperature of the IC increases. The increases in the current through, and the resistance of, the weak pull-up circuit with rising temperature caused by the leakage current may cause an input buffer circuit coupled to the pad to sense an incorrect bit value at the pad when an external driver circuit is driving an input signal to the pad.

According to some examples disclosed herein, a leakage current sensing circuit is provided in a weak pull-up circuit in an integrated circuit (IC). The leakage current sensing circuit includes an n-channel transistor biased in an off state. The leakage current sensing circuit also includes a current mirror circuit that generates a compensation current based on the current through the n-channel transistor. The weak pull-up circuit provides the compensation current to a pad when the weak pull-up circuit is enabled. The amount of compensation current is large enough to compensate for the leakage current through a driver circuit coupled to the same pad, so that the resulting current through the weak pull-up circuit is close to an ideal current.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs) and programmable logic devices. As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially fewer configurable features than soft logic or no configurable features.

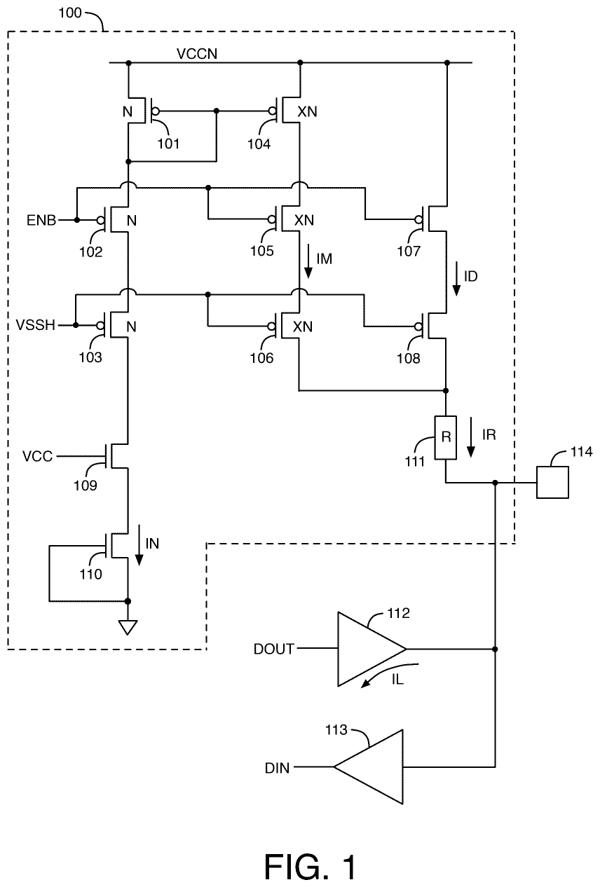

FIG. 1 is a diagram that illustrates an example of a weak pull-up circuit 100 that includes a leakage current sensing circuit that compensates for leakage current through an output driver circuit. The weak pull-up circuit 100 of Figure (FIG.) 1 is in an integrated circuit (IC). The weak pull-up circuit 100 can be in any type of IC, such as a configurable IC (e.g., a field programmable gate array (FPGA) or programmable logic device (PLD)), a microprocessor IC, a graphics processing unit IC, a memory IC, an application specific IC, a transceiver IC, etc.

The weak pull-up circuit 100 of FIG. 1 includes 8 p-channel field-effect transistors (FETs) 101-108, 2 n-channel FETs 109-110, and an on-chip resistor 111. The FETs 101-110 can be, as examples, MOSFETs (i.e., metal oxide semiconductor FETs) or other types of FETs. The FETs 101, 104, and 107 are coupled to a supply rail at a first supply voltage VCCN (e.g., 1 volt). The weak pull-up circuit 100 is coupled to an external pad 114 of the IC (also referred to herein as a pad), an output driver circuit 112, and an input buffer circuit 113. The output driver circuit 112 and the input buffer circuit 113 are coupled to the pad 114 as shown in FIG. 1.

The weak pull-up circuit 100 is enabled to pull the voltage at the pad 114 to a logic high state using a weak pull-up current IR through resistor 111 when a driver circuit that is external to the IC of FIG. 1 is driving an input signal to the pad 114 during a receive mode. The input buffer circuit 113 buffers the input signal received at pad 114 during the receive mode and drives the buffered input signal DIN to other circuitry in the IC (not shown). The weak pull-up circuit 100 can also be enabled to pull the voltage at pad 114 to a logic high state using the weak pull-up current IR through resistor 111 when the pad 114 is unused and no other signal is present at the pad 114.

During a transmission mode, the output driver circuit 112 is enabled to drive data or control information indicated by an output signal DOUT through pad 114 to an external device, and the weak pull-up circuit 100 is disabled. The output driver circuit 112 is disabled (i.e., turned off) during the receive mode when the input signal is driven through pad 114 and buffered by input buffer circuit 113, as described above. The output driver circuit 112 may draw significant leakage current IL from the pad 114 when the output driver circuit 112 is disabled, and the weak pull-up circuit 100 is enabled (e.g., during receive mode or when pad 114 is unused). The leakage current IL through output driver circuit 112 may cause the current IR through the weak pull-up circuit 100 to decrease more, and the resistance of the weak pull-up circuit 100 to increase more, than ideal amounts, as the temperature of the IC increases.

The gate of the n-channel transistor 110 in the weak pull-up circuit 100 is coupled to the source of the n-channel transistor 110 at ground to cause the n-channel transistor 110 to be off. When the n-channel transistor 110 is off, n-channel transistor 110 generates a small leakage current IN that equals the leakage current through one of the n-channel FETs in the output driver circuit 112 that draws a portion of the leakage current IL when the output driver circuit 112 is disabled. The gate of the n-channel transistor 109 is coupled to receive a second supply voltage VCC (e.g., 0.75 volts) that is less than supply voltage VCCN.

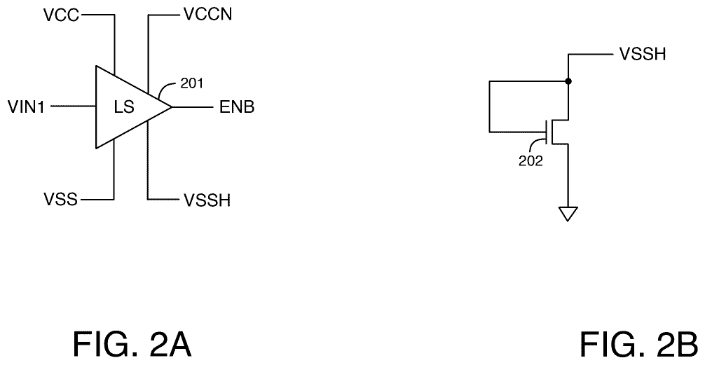

A varying enable bar signal ENB is provided to the gate of each of the three p-channel transistors 102, 105, and 107. FIG. 2A illustrates an example of a level shifter circuit 201 that generates the enable bar signal ENB of FIG. 1 using a first input voltage signal VIN1. The level shifter circuit 201 receives the first supply voltage VCCN and the second supply voltage VCC that are also shown in FIG. 1. Level shifter circuit 201 also receives a low voltage VSSH and a ground voltage VSS. Level shifter circuit 201 varies the voltage of signal ENB between supply voltage VCCN and voltage VSSH in response to the voltage of input voltage signal VIN1.

The voltage VSSH is provided to the gate of each of the three p-channel transistors 103, 106, and 108. FIG. 2B illustrates an example of a voltage generator circuit 202 that generates the voltage VSSH of FIG. 1 and FIG. 2A. The voltage generator circuit 202 is a diode connected n-channel field-effect transistor (FET) that is always on to pull the voltage VSSH to a low voltage (e.g., 0.25 volts) near ground (e.g., at voltage VSS). The gate of transistor 202 is coupled to the drain of transistor 202. The purpose of voltage VSSH is to bias the p-channel transistors 103, 106, and 108 in the stack configuration of FIG. 1 to protect all the p-channel transistors of FIG. 1 from EOS (electrical over stress).

To disable the weak pull-up circuit 100 (e.g., during the transmission mode), the level shifter circuit 201 increases the voltage of the enable bar signal ENB to the supply voltage VCCN (e.g., 1 volt) to turn off transistors 102, 105, and 107. Transistors 103, 106, and 108 are off when the weak pull-up circuit 100 is disabled. To enable the weak pull-up circuit 100 (e.g., during receive mode), the level shifter circuit 201 decreases the voltage of the enable bar signal ENB to voltage VSSH (e.g., 0.25 volts) to turn on transistors 102, 105, and 107. The voltage generator circuit 202 causes transistors 103, 106, and 108 to be on when the weak pull-up circuit 100 is enabled, because voltage generator circuit 202 pulls voltage VSSH to a low voltage (e.g., 0.25 volts).

P-channel transistors 101 and 104 are coupled as a current mirror circuit. Each of the p-channel transistors 101-103 has the same size that equals a number N, and each of the p-channel transistors 104-106 has the same size that equals XN (i.e., X×N), where X is a positive number greater than 1. Thus, each of the transistors 104-106 is X times larger than each of the transistors 101-103. Transistors 101-103 and 109-110 are coupled between the supply rail at VCCN and a ground terminal (e.g., at voltage VSS), as shown in FIG. 1. Transistors 104-106 are coupled between the supply rail at VCCN and resistor 111, as shown in FIG. 1. Transistors 107-108 are also coupled between the supply rail at VCCN and resistor 111, as shown in FIG. 1.

When the weak pull-up circuit 100 is enabled in response to signal ENB, the transistors 101-106 and 109-110 form a leakage current sensing circuit that mirrors the current IN through the n-channel transistor 110 that is biased in an off state. The current mirror circuit formed by transistors 101 and 104 generates a compensation current IM through transistors 104-106 that is a multiplication factor X of the current IN through the transistors 101-103 and 109-110. Thus, the compensation current IM equals the current IN times X (i.e., IM=IN×X). The current IM that flows through transistors 104-106 and the current ID that flows through transistors 107-108 are added together in the resistor 111 to generate the weak pull-up current IR through the resistor 111 when the weak pull-up circuit 100 is enabled.

The amount (i.e., in Amperes) of the compensation current IM is large enough to compensate for the leakage current IL through output driver circuit 112 so that the total current IR through the resistor 111 is close to an ideal current when the weak pull-up circuit 100 is enabled. The compensation current IM causes both the current IR through resistor 111 to decrease with rising temperature and the resistance of the weak pull-up circuit 100 to increase with rising temperature at rates that are close to the ideal values that would occur without the leakage current IL through the output driver circuit 112.

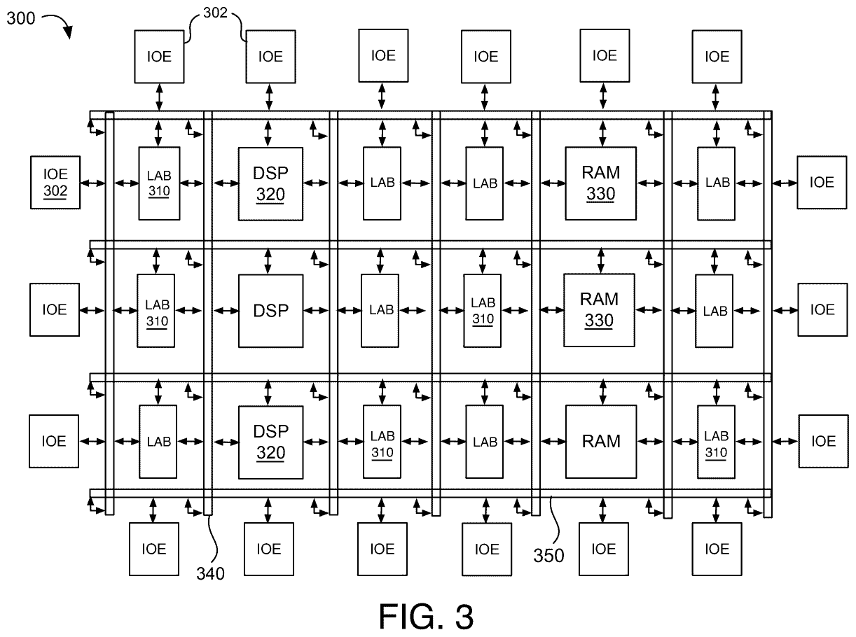

Figure (FIG.) 3 is a diagram that illustrates an example of a configurable logic IC 300 that can implement techniques disclosed herein. The circuits disclosed herein with respect to FIGS. 1 and 2A-2B can be formed in the configurable logic IC 300 according to an example. As shown in FIG. 3, the configurable logic IC 300 includes a two-dimensional array of configurable functional circuit blocks, including configurable logic array blocks (LABs) 310 and other functional circuit blocks, such as random access memory (RAM) blocks 330 and digital signal processing (DSP) blocks 320. Functional blocks such as LABs 310 can include smaller configurable logic circuits (e.g., logic elements, logic blocks, or adaptive logic modules) that receive input signals and perform custom functions on the input signals to produce output signals.

In addition, configurable logic IC 300 can have input/output elements (IOEs) 302 for driving signals off of configurable logic IC 300 and for receiving signals from other devices. IOEs 302 may include parallel input/output circuitry, serial data transceiver circuitry, differential receiver and transmitter circuitry, or other circuitry used to connect one integrated circuit to another integrated circuit. As shown, IOEs 302 may be located around the periphery of the chip. If desired, the configurable logic IC 300 may have IOEs 302 arranged in different ways. For example, IOEs 302 may form one or more columns, rows, or islands of input/output elements that may be located anywhere on the configurable IC 300. Input/output elements 302 can include general purpose input/output (GPIO) circuitry (e.g., on the top and bottoms edges of IC 300), high-speed input/output (HSIO) circuitry (e.g., on the left edge of IC 300), and on-package input/output (OPIOs) circuitry (e.g., on the right edge of IC 300).

The configurable logic IC 300 can also include programmable interconnect circuitry in the form of vertical routing channels 340 (i.e., interconnects formed along a vertical axis of configurable logic IC 300) and horizontal routing channels 350 (i.e., interconnects formed along a horizontal axis of configurable logic IC 300), each routing channel including at least one track to route at least one wire. One or more of the routing channels 340 and/or 350 can be part of a network-on-chip (NOC) having router circuits.

Note that other routing topologies, besides the topology of the interconnect circuitry depicted in FIG. 3, can be used. For example, the routing topology may include wires that travel diagonally or that travel horizontally and vertically along different parts of their extent as well as wires that are perpendicular to the device plane in the case of three dimensional integrated circuits. The driver of a wire may be located at a different point than one end of a wire.

Furthermore, it should be understood that embodiments disclosed herein with respect to FIGS. 1 and 2A-2B can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Configurable logic IC 300 can contain programmable memory elements. Memory elements can be loaded with configuration data bits using IOEs 302. Once loaded, the memory elements each provide a corresponding static control signal that controls the operation of an associated configurable functional block (e.g., LABs 310, DSP blocks 320, RAM blocks 330, or IOEs 302). The configuration data bits can set the functions of the configurable functional circuit blocks (i.e., soft logic) in IC 300.

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data bits during programming, the memory elements are sometimes referred to as configuration memory or programmable memory elements.

The memory elements can be organized in a configuration memory array consisting of rows and columns. A data register that spans across all columns and an address register that spans across all rows may receive configuration data bits. The configuration data bits can be shifted onto the data register. When the appropriate address register is asserted, the data register writes the configuration data bits to the configuration memory bits of the row that was designated by the address register.

Configurable integrated circuit 300 can include configuration memory that is organized in sectors, whereby a sector can include the configuration bits that specify the function and/or interconnections of the subcomponents and wires in or crossing that sector. Each sector can include separate data and address registers.

The configurable IC of FIG. 3 is merely one example of an IC that can include embodiments disclosed herein. The embodiments disclosed herein may be incorporated into any suitable integrated circuit or system. For example, the embodiments disclosed herein can be incorporated into numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein may be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

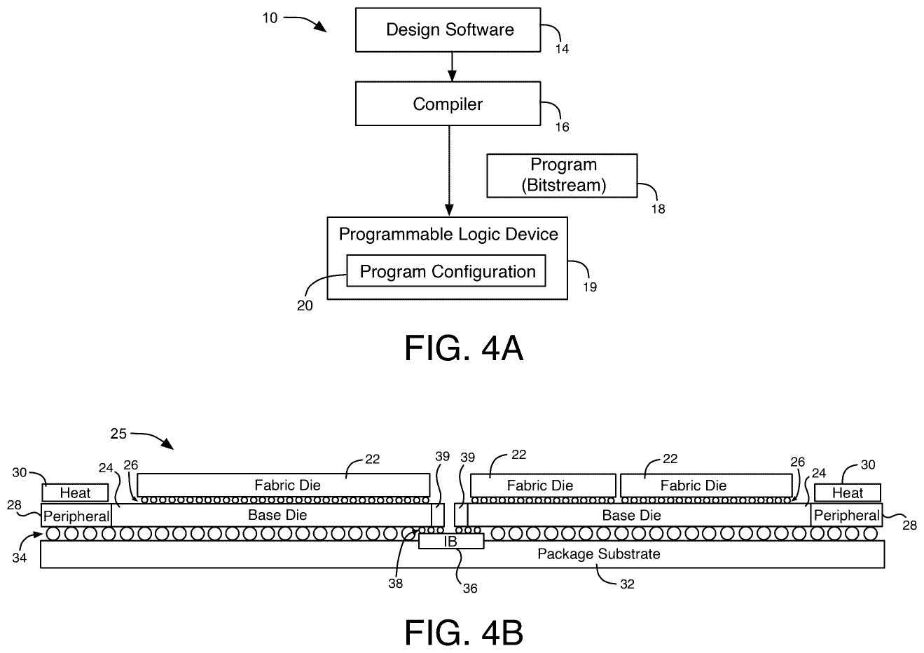

FIG. 4A illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized tasks.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 4B, but many others can be used, and it should be understood that this disclosure is intended to encompass any suitable programmable logic device where programmable logic fabric and fabric support circuitry are at least partially separated on different integrated circuit die.

FIG. 4B is a diagram that depicts an example of the programmable logic device 25 that includes three fabric die 22 and two base die 24 that are connected to one another via microbumps 26. In the example of FIG. 4B, at least some of the programmable logic fabric of the programmable logic device 25 is in the three fabric die 22, and at least some of the fabric support circuitry that operates the programmable logic fabric is in the two base die 24. For example, some of the circuitry of configurable IC 300 shown in FIG. 3 (e.g., LABs 310, DSP 320, RAM 330) can be located in the fabric die 22 and some of the circuitry of IC 300 (e.g., input/output elements 302) can be located in the base die 24.

Although the fabric die 22 and base die 24 appear in a one-to-one relationship or a two-to-one relationship in FIG. 4B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 25. The heat spreaders 30 can appear above, as pictured, and/or below the package (e.g., as a double-sided heat sink). The base die 24 can attach to a package substrate 32 via conductive bumps 34. In the example of FIG. 4B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 25 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

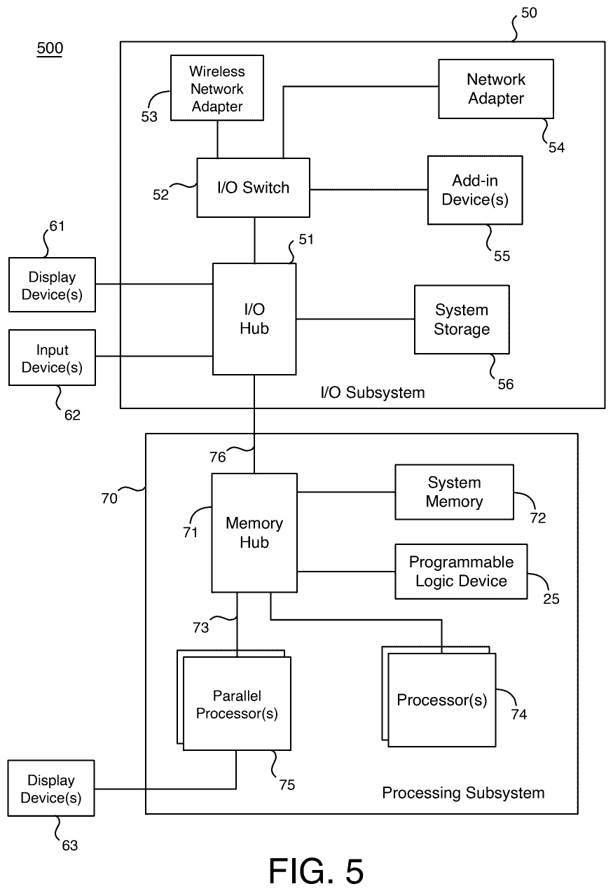

FIG. 5 is a block diagram illustrating a computing system 500 configured to implement one or more aspects of the embodiments described herein. The computing system 500 includes a processing subsystem 70 having one or more processor(s) 74, a system memory 72, and a programmable logic device 25 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 500 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 500. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 500 can include other components not shown in FIG. 5, including other port connections, optical storage drives, video capture devices, and the like, that can also be connected to the I/O hub 51. Communication paths interconnecting the various components in FIG. 5 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 500 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 500 can be integrated into a single package to form a system in package (SIP) configuration. In one embodiment, at least a portion of the components of the computing system 500 can be integrated into a multi-chip module (MCM), which can be interconnected with other multi-chip modules into a modular computing system.

The computing system 500 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 500. For example, any number of add-in cards or peripherals can be supported, or some components can be eliminated. Furthermore, some architectures can use different terminology for components similar to those illustrated in FIG. 5. For example, the memory hub 71 can be referred to as a Northbridge in some architectures, while the I/O hub 51 can be referred to as a Southbridge.

Example 1 is an integrated circuit comprising: an output driver circuit coupled to a pad of the integrated circuit; and a weak pull-up circuit coupled to the pad, wherein the weak pull-up circuit comprises a resistor and a leakage current sensing circuit coupled to the resistor, and wherein the leakage current sensing circuit generates a compensation current in the resistor that compensates for a first leakage current through the output driver circuit when the output driver circuit is disabled.

In Example 2, the integrated circuit of Example 1 may optionally include, wherein the weak pull-up circuit further comprises first and second transistors coupled between a supply rail and the resistor, and wherein a third current through the resistor equals the compensation current plus a fourth current through the first and the second transistors.

In Example 3, the integrated circuit of any one of Examples 1-2 may optionally include, wherein the leakage current sensing circuit comprises an n-channel transistor, and wherein a gate of the n-channel transistor is coupled to a source of the n-channel transistor.

In Example 4, the integrated circuit of any one of Examples 1-3 may optionally include, wherein the leakage current sensing circuit comprises a current mirror circuit that generates the compensation current.

In Example 5, the integrated circuit of any one of Examples 1-4 may optionally include, wherein the leakage current sensing circuit comprises a current mirror circuit that generates the compensation current by multiplying a third current through a transistor that is biased in an off state.

In Example 6, the integrated circuit of any one of Examples 1-5 further comprises an input buffer circuit coupled to the pad, wherein the weak pull-up circuit is enabled to generate the compensation current through the resistor in response to a voltage when the input buffer circuit is enabled to buffer an input signal received at the pad.

In Example 7, the integrated circuit of any one of Examples 1-6 may optionally include, wherein the leakage current sensing circuit comprises a current mirror circuit that generates the compensation current through first transistors based on a third current through second transistors, and wherein the third current equals a second leakage current through one of the second transistors.

In Example 8, the integrated circuit of any one of Examples 1-7 may optionally include, wherein the leakage current sensing circuit comprises first and second transistors, and wherein the leakage current sensing circuit is enabled and disabled in response to a voltage signal provided to the first transistor and to the second transistor.

Example 9 is a method for operating a weak pull-up circuit in an integrated circuit, the method comprising: enabling the weak pull-up circuit, wherein the weak pull-up circuit is coupled to a pad of the integrated circuit; and generating a compensation current in the weak pull-up circuit based on a first leakage current through a first transistor, wherein the compensation current compensates for a second leakage current from the pad through an output driver circuit when the output driver circuit is disabled.

In Example 10, the method of Example 9 may optionally include, wherein generating the compensation current in the weak pull-up circuit further comprises multiplying the first leakage current using a current mirror circuit to generate the compensation current.

In Example 11, the method of any one of Examples 9-10 may optionally include, wherein enabling the weak pull-up circuit comprises enabling the weak pull-up circuit to generate the compensation current in response to a voltage signal when an input buffer circuit is enabled to buffer an input signal received at the pad.

In Example 12, the method of any one of Examples 9-11 may optionally include, wherein generating the compensation current in the weak pull-up circuit further comprises generating the compensation current through a resistor in the weak pull-up circuit.

In Example 13, the method of any one of Examples 9-12 may optionally include, wherein the first transistor is biased in an off state when the weak pull-up circuit is enabled.

In Example 14, the method of any one of Examples 9-13 further comprises generating a fourth current through second transistors in the weak pull-up circuit; and providing the fourth current and the compensation current through a resistor to the pad, wherein the resistor is in the weak pull-up circuit.

In Example 15, the method of any one of Examples 9-14 may optionally include, wherein generating the compensation current in the weak pull-up circuit further comprises generating the compensation current with a current mirror circuit based on the first leakage current provided through a second transistor to the first transistor to generate the compensation current through a third transistor in the weak pull-up circuit, and wherein the compensation current is provided to the pad.

Example 16 is a weak pull-up circuit comprising: a first transistor that is biased in an off state; a current mirror circuit that generates a first current based on a second current through the first transistor; and a resistor, wherein the first current is provided through the resistor to a pad, and wherein the first current compensates for a leakage current through an output driver circuit that is coupled to the pad and to the weak pull-up circuit.

In Example 17, the weak pull-up circuit of Example 16 further comprises second transistors that generate a fourth current provided to the resistor, wherein a fifth current through the resistor equals the first current plus the fourth current.

In Example 18, the weak pull-up circuit of any one of Examples 16-17 further comprises a second transistor coupled to the resistor, wherein the current mirror circuit generates the first current through the second transistor.

In Example 19, the weak pull-up circuit of any one of Examples 16-18 further comprises a second transistor coupled to the current mirror circuit, wherein the second transistor is controlled by a voltage that enables the weak pull-up circuit; and a third transistor coupled to the current mirror circuit, wherein the third transistor is controlled by the voltage that enables the weak pull-up circuit.

In Example 20, the weak pull-up circuit of any one of Examples 16-19 may optionally include, wherein the first transistor is an n-channel field-effect transistor comprising a gate and a source coupled to the gate.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
an output driver circuit coupled to a pad of the integrated circuit; and
a weak pull-up circuit coupled to the pad, wherein the weak pull-up circuit comprises a resistor and a leakage current sensing circuit coupled to the resistor, and wherein the leakage current sensing circuit generates a compensation current in the resistor that compensates for a first leakage current through the output driver circuit when the output driver circuit is disabled.

2. The integrated circuit of claim 1, wherein the weak pull-up circuit further comprises first and second transistors coupled between a supply rail and the resistor, and wherein a third current through the resistor equals the compensation current plus a fourth current through the first and the second transistors.

3. The integrated circuit of claim 1, wherein the leakage current sensing circuit comprises an n-channel transistor, and wherein a gate of the n-channel transistor is coupled to a source of the n-channel transistor.

4. The integrated circuit of claim 1, wherein the leakage current sensing circuit comprises a current mirror circuit that generates the compensation current.

5. The integrated circuit of claim 1, wherein the leakage current sensing circuit comprises a current mirror circuit that generates the compensation current by multiplying a third current through a transistor that is biased in an off state.

6. The integrated circuit of claim 1 further comprising:
an input buffer circuit coupled to the pad, wherein the weak pull-up circuit is enabled to generate the compensation current through the resistor in response to a voltage when the input buffer circuit is enabled to buffer an input signal received at the pad.

7. The integrated circuit of claim 1, wherein the leakage current sensing circuit comprises a current mirror circuit that generates the compensation current through first transistors based on a third current through second transistors, and wherein the third current equals a second leakage current through one of the second transistors.

8. The integrated circuit of claim 1, wherein the leakage current sensing circuit comprises first and second transistors, and wherein the leakage current sensing circuit is enabled and disabled in response to a voltage signal provided to the first transistor and to the second transistor.

9. A method for operating a weak pull-up circuit in an integrated circuit, the method comprising:
enabling the weak pull-up circuit, wherein the weak pull-up circuit is coupled to a pad of the integrated circuit; and
generating a compensation current in the weak pull-up circuit based on a first leakage current through a first transistor, wherein the compensation current compensates for a second leakage current from the pad through an output driver circuit when the output driver circuit is disabled.

10. The method of claim 9, wherein generating the compensation current in the weak pull-up circuit further comprises multiplying the first leakage current using a current mirror circuit to generate the compensation current.

11. The method of claim 9, wherein enabling the weak pull-up circuit comprises enabling the weak pull-up circuit to generate the compensation current in response to a voltage signal when an input buffer circuit is enabled to buffer an input signal received at the pad.

12. The method of claim 9, wherein generating the compensation current in the weak pull-up circuit further comprises generating the compensation current through a resistor in the weak pull-up circuit.

13. The method of claim 9, wherein the first transistor is biased in an off state when the weak pull-up circuit is enabled.

14. The method of claim 9 further comprising:
generating a fourth current through second transistors in the weak pull-up circuit; and
providing the fourth current and the compensation current through a resistor to the pad, wherein the resistor is in the weak pull-up circuit.

15. The method of claim 9, wherein generating the compensation current in the weak pull-up circuit further comprises generating the compensation current with a current mirror circuit based on the first leakage current provided through a second transistor to the first transistor to generate the compensation current through a third transistor in the weak pull-up circuit, and wherein the compensation current is provided to the pad.

16. A weak pull-up circuit comprising:
a first transistor that is biased in an off state;
a current mirror circuit that generates a first current based on a second current through the first transistor; and
a resistor, wherein the first current is provided through the resistor to a pad, and wherein the first current compensates for a leakage current through an output driver circuit that is coupled to the pad and to the weak pull-up circuit.

17. The weak pull-up circuit of claim 16 further comprising:
second transistors that generate a fourth current provided to the resistor, wherein a fifth current through the resistor equals the first current plus the fourth current.

18. The weak pull-up circuit of claim 16 further comprising:
a second transistor coupled to the resistor, wherein the current mirror circuit generates the first current through the second transistor.

19. The weak pull-up circuit of claim 16 further comprising:
a second transistor coupled to the current mirror circuit, wherein the second transistor is controlled by a voltage that enables the weak pull-up circuit; and
a third transistor coupled to the current mirror circuit, wherein the third transistor is controlled by the voltage that enables the weak pull-up circuit.

20. The weak pull-up circuit of claim 16, wherein the first transistor is an n-channel field-effect transistor comprising a gate and a source coupled to the gate.
